(19) United States
(12) Patent Application Publication
(10) Pub. No.: US 2023/0335973 A1
(43) Pub. Date: Oct. 19, 2023

(54) SEMICONDUCTOR LASER ELEMENT

(71) Applicants: Technion Research & Development Foundation Limited, Technion City (IL); Nichia Corporation, (US)

(72) Inventors: Mordechai SEGEV, Haifa (IL); Gal HARARI, Tel Aviv Yafo (IL); Shinji TOHI, Haifa (IL); Kunimichi OMAE, Anan-shi (JP); Takumi ITO, Tokushima-shi (JP)

(73) Assignees: Technion Research & Development Foundation Limited, Technion City (IL); Nichia Corporation, Anan-shi (JP)

(21) Appl. No.: 17/721,073

(22) Filed: Apr. 14, 2022

(51) Int. Cl. H01S 5/10; H01S 5/042; H01S 5/12

(52) U.S. Cl. CPC H01S 5/1071; H01S 5/04256; H01S 5/1231

(57) ABSTRACT

A semiconductor laser element a first ring resonator. The first ring resonator includes a first semiconductor stack including a first n-side semiconductor layer, a first p-side semiconductor layer, and a first active layer located between the first n-side semiconductor layer and the first A-side semiconductor layer, wherein the first ring resonator comprises a diffraction grating. The semiconductor laser element further includes a second ring resonator optically coupled to the first ring resonator by evanescent field coupling. The second ring resonator includes a second semiconductor stack including a second n-side semiconductor layer, a second p-side semiconductor layer, and a second active layer located between the second n-side semiconductor layer and the second p-side semiconductor layer, wherein a peak wavelength of light emitted by the second ring resonator is the same as a peak wavelength of light emitted by the first ring resonator.

### BACKGROUND

The present disclosure relates generally to semiconductor laser elements, and specifically, semiconductor laser elements that include optically coupled ring resonators.

Optical ring resonators (or “ring lasers”) are formed of ring-shaped waveguides in which light circulates to cause lasing. Optical ring resonators in which a diffraction grating is integrated into the waveguide are known as distributed feedback (DFB) ring resonators (or “DFB ring lasers”). DFB ring resonators induce single-mode lasing, in which the single mode matches the diffraction grating pitch.

Recently proposed and demonstrated topological insulator lasers are now attracting attention, as they allow for a robust array of many diode lasers acting together as a single coherent high-power laser source. Such lasers, composed of a two-dimensional ring laser array, have a lasing mode localized at a perimeter of the array. Consequently, the lasing mode is robust to defects and disorder caused by a fabrication imperfection.

### SUMMARY

To construct single coherent high-power laser sources, the constituent lasing elements need to be coupled to one another in a predesigned way, and preferably each resonator should lase in a single cavity mode. These requirements are hard to achieve in short wavelengths, and in strongly confined and highly multimode cavities, as encountered in current GaN lasers.

Certain embodiments described herein can provide a semiconductor laser element that achieves high brightness and high power single mode lasing, and that may be used in a lasing array in high power lasers on chips, integrated photonic systems, and more.

In one embodiment, a semiconductor laser element includes a first ring resonator. The first ring resonator includes a first semiconductor stack including a first n-side semiconductor layer, a first p-side semiconductor layer, and a first active layer located between the first n-side semiconductor layer and the first p-side semiconductor layer, wherein the first ring resonator includes a diffraction grating. The semiconductor laser element further includes a second ring resonator optically coupled to the first ring resonator by evanescent field coupling. The second ring resonator includes a second semiconductor stack including a second n-side semiconductor layer, a second p-side semiconductor layer, and a second active layer located between the second n-side semiconductor layer and the second p-side semiconductor layer, wherein a peak wavelength of light emitted by the second ring resonator is the same as a peak wavelength of light emitted by the first ring resonator.

In another embodiment, a method of forming a semiconductor laser element includes forming a semiconductor stack that includes an n-side semiconductor layer, a p-side semiconductor layer, and an active layer located between the n-side semiconductor layer and the p-side semiconductor layer. The method further includes forming a mask on the semiconductor stack, wherein the mask includes a first ring-shaped portion and a second ring-shaped portion, wherein a periodic structure is located at an inner lateral surface or outer lateral surface of the first ring-shaped portion. The method further includes dry etching the semiconductor stack to form a first ring resonator corresponding to the first ring-shaped portion and a second ring resonator corresponding to the second ring-shaped portion, the first ring resonator comprising a diffraction grating corresponding to the periodic structure, wherein the dry etching is performed at a pressure in a range of 0.1 Pa to 5.0 Pa.

This summary is illustrative only and is not intended to be in any way limiting.

### BRIEF DESCRIPTION OF THE DRAWINGS

The disclosure will become more fully understood from the following detailed description, taken in conjunction with the accompanying figures, wherein like reference numerals refer to like elements, in which:

FIG. 1A is a uniform ring resonator, according to an exemplary embodiment;

FIG. 1B is a spectrum graph of the uniform ring resonator of FIG. 1A.

FIG. 1C is a DFB ring resonator, according to an exemplary embodiment;

FIG. 1D is a spectrum graph of the DFB ring resonator of FIG. 1C;

FIG. 2A is a top view of a semiconductor laser element, according to an exemplary embodiment;

FIG. 2B is a side cross-sectional view taken along a line IIB-IIB of the semiconductor laser element of FIG. 2A;

FIG. 3A is a top view of a waveguide corresponding to a curved portion of a first ring resonator of the semiconductor laser element of FIG. 2A;

FIG. 3B is a close-up view of a diffraction grating on a DFB waveguide, according to an exemplary embodiment;

FIG. 3C is another top view of a DFB waveguide corresponding to a curved portion of a first ring resonator of the semiconductor laser element of FIG. 2A;

FIG. 3D is an exemplary side cross-sectional view taken along a line IIID-IIID of the waveguide of FIG. 3C;

FIG. 3E is another exemplary side cross-sectional view taken along a line IIID-IIID of the waveguide of FIG. 3C;

FIGS. 4A-B are alternate embodiments of ring resonators, according to exemplary embodiments;

FIG. 5A is a spectrum graph of a DFB ring resonator, according to an exemplary embodiment;

FIG. 5B is a spectrum graph of a semiconductor laser element, according to an exemplary embodiment;

FIG. 6 is a flow diagram of a method of forming a semiconductor laser element, according to an exemplary embodiment;

FIGS. 7A-7I are depictions of the steps of the method of FIG. 6, according to exemplary embodiments;

FIG. 8 is a side view of a semiconductor stack, according to an exemplary embodiment;

FIGS. 9A-B are close-up view of diffraction gratings formed under different pressures, according to an exemplary embodiment;

FIG. 10 is a top view of a semiconductor laser element, according to an exemplary embodiment;

FIG. 11 is a side cross-sectional view of the semiconductor laser element of FIG. 10; and

FIGS. 12A-B are lasing mode graphs of experimental results of a semiconductor laser element, according to an exemplary embodiment.

### DETAILED DESCRIPTION

Before turning to the figures, which illustrate certain exemplary embodiments in detail, it should be understood that the present disclosure is not limited to the details or methodology set forth in the description or illustrated in the figures. It should also be understood that the terminology used herein is for the purpose of description only and should not be regarded as limiting. Examples of specific implementations and applications are provided primarily for illustrative purposes.

Implementations herein relate to systems, methods, and apparatuses related to a semiconductor laser element configured to produce single-mode lasing (e.g., single peak in a lasing spectrum) in a laser system. The semiconductor laser element includes coupled ring resonators. Each ring resonator comprises a semiconductor stack including at least an n-side semiconductor layer, a p-side semiconductor layer, and an active layer disposed between the n-side semiconductor layer and the p-side semiconductor layer. One of the two ring resonators includes a diffraction grating that produces a single-mode lasing of a set wavelength. The other ring resonator (e.g., ring resonator without a diffraction grating), amplifies the light with the set wavelength. The two ring resonators are optically coupled via evanescent field coupling.

As used herein, the terms “p-side/p-type” refer to the positive-side that includes a plurality of electron holes and the terms “n-side/n-type” refer to the negative-side that includes an excess of electrons in the outer shells of electrically neutral atoms.

As used herein, the term “waveguide”, “optical waveguide,” or the like refers to a structure that guides waves, such as electromagnetic waves (e.g., light, etc.), with minimal loss of energy by restricting electromagnetic wave direction. The geometry of a waveguide alters function of the waveguide and the modes of the wave formed in the waveguide.

As used herein, the term “ring resonator,” “optical ring resonator,” or the like refers to a waveguide that is configured in a closed loop. Ring resonators operate on principles of total internal reflection and constructive interference to produce light of resonant wavelengths. Ring resonators function as a filter, allowing only certain wavelengths to resonate within the loop. The geometry of a ring resonator affects the wavelengths that may resonate within the loop.

### Ring Resonators

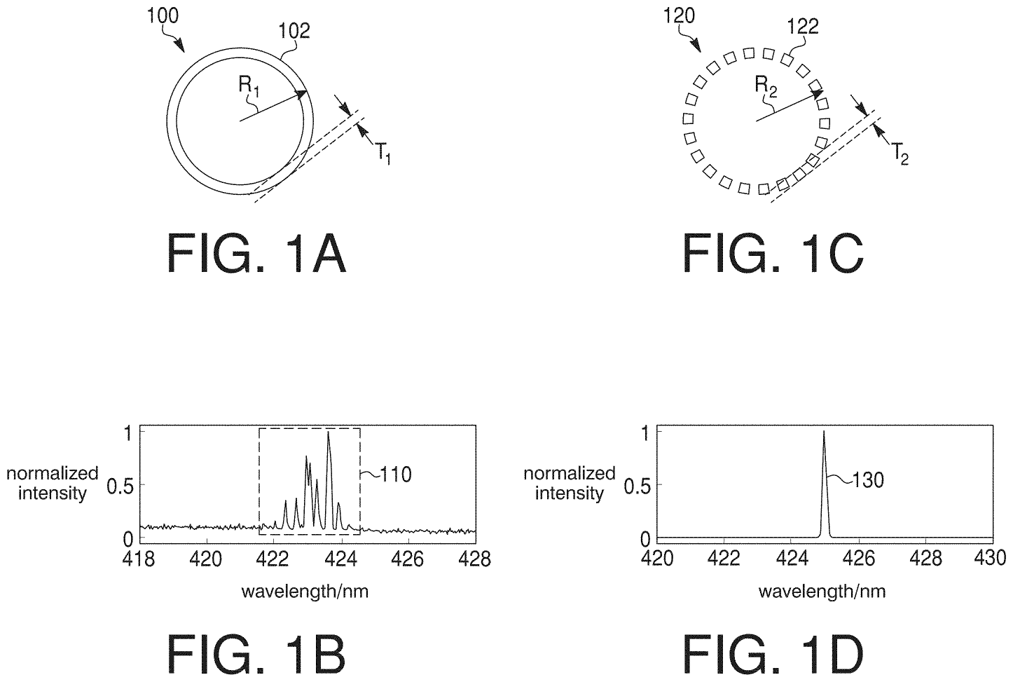

Referring generally to FIGS. 1A-1D, the effect of a diffraction grating on a ring resonator is shown. As seen in FIGS. 1A-1D, a DFB ring resonator (e.g., ring resonator including a diffraction grating) filters out modes otherwise formed by a uniform ring resonator and causes single-mode lasing in a longitudinal mode.

Referring now to FIG. 1A, a uniform ring resonator 100 is shown, according to an exemplary embodiment. The uniform ring resonator 100 amplifies and emits light. The uniform ring resonator 100 is a circular ring resonator having a radius R₁. The radius R₁ is defined as the radius of the uniform ring resonator 100 as measured to an outer surface of the uniform ring resonator 100. In some embodiments, the radius R₁ may be in a range of 3 μm to 5000 μm. The uniform ring resonator 100 is formed of a uniform waveguide 102. The uniform waveguide 102 is a waveguide having a substantially uniform (e.g., constant, unchanging, etc.) lateral thickness T₁, defined by the distance between the inner and outer surfaces of the uniform waveguide 102. In some embodiments, the lateral thickness T₁ is in the range of 0.3 μm to 10 μm, preferably 0.4 μm to 2.0 μm. In some embodiments, the lateral thickness T₁ is 480 nanometers (nm). The radius R₁ and the lateral thickness T₁ may be configured for a specific application of the uniform ring resonator 100.

Referring now to FIG. 1B, a spectrum graph of a uniform ring resonator, such as uniform ring resonator 100 of FIG. 1A, is shown. The spectrum graph shows the normalized intensity of wavelengths of light formed by the uniform ring resonator 100. The spectrum graph includes multiple peaks 110, thus indicating that the uniform ring resonator 100 forms multi-mode light. Each peak of the multiple peaks 110 corresponds to a different wavelength of light emitted by the uniform ring resonator 100. In applications where single-mode lasing may be desirable, the multi-mode lasing produced by the uniform ring resonator 100 may be undesirable.

Referring now to FIG. 1C, a DFB ring resonator 120 is shown, according to an exemplary embodiment. Similar to the uniform ring resonator, the DFB ring resonator 120 is a circular ring resonator defining a radius R₂. The radius R₂ is defined as the radius of the DFB ring resonator 120 as measured to an outer surface of the DFB ring resonator 120. The DFB ring resonator 120 amplifies and emits light, similar to the uniform ring resonator 100. However, the DFB ring resonator 120 is formed of a DFB waveguide 122. The DFB waveguide 122 is a waveguide that includes a diffraction grating. The diffraction grating may be disposed at a lateral surface (e.g., inner lateral surface and/or outer lateral surface), at an upper surface of the waveguide, or embedded within the waveguide. The diffraction grating causes a single intended wavelength to be emitted, thus inducing single-mode lasing. The radius R₂ and the diffraction grating of the DFB waveguide 122 may be configured for a specific application of the DFB ring resonator 120. The pitch of the diffraction grating determines the wavelength of light emitted by the DFB ring resonator 120. Since the DFB waveguide 122 includes a diffraction grating, the lateral thickness of the DFB waveguide 122 may vary. However, the DFB waveguide 122 has a maximum lateral thickness T₂ defined by the distance between peaks on the inner and outer surface of the DFB waveguide 122. The maximum lateral thickness T₂ may be configured for a specific application of the DFB ring resonator 120.

Referring now to FIG. 1D, a spectrum graph of a DFB ring resonator, such as the DFB ring resonator 120 of FIG. 1C, is shown. The spectrum graph shows the normalized intensity of wavelengths of light emitted by the DFB ring resonator 120. The DFB ring resonator 120 causes single-mode light, as the spectrum graph only includes a single wavelength peak 130, which corresponds to a single peak of light emitted by the DFB ring resonator 120.

### Example Embodiments of Semiconductor Laser Element

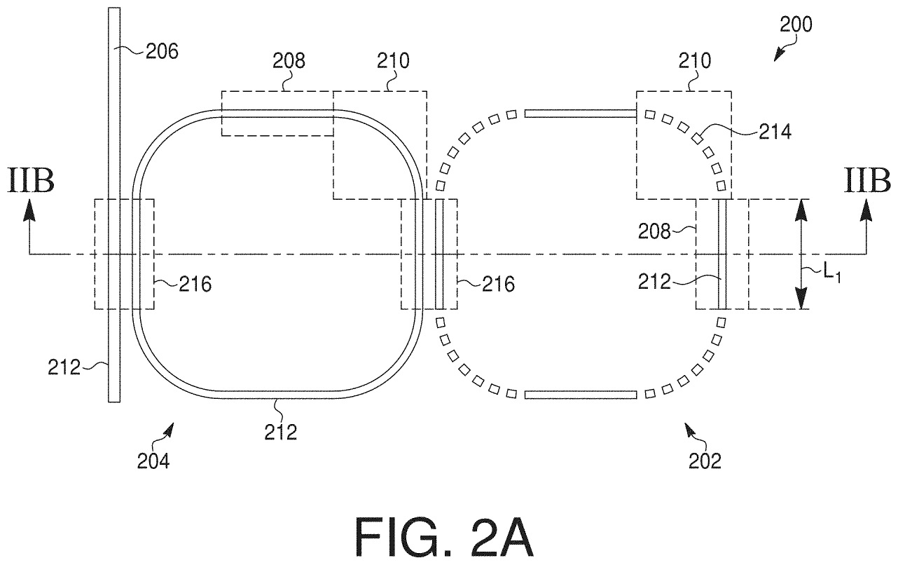

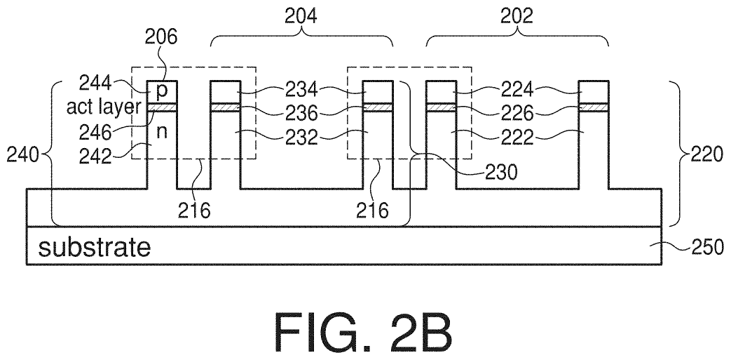

Referring now to FIG. 2A, a top view of a semiconductor laser element 200 is shown, according to an exemplary embodiment. The semiconductor laser element 200 includes optically coupled ring resonators that form and amplify single-mode lasing and act as a master oscillator power amplifier (MOPA). The semiconductor laser element 200 includes a first ring resonator 202 and a second ring resonator 204 optically coupled to the first ring resonator 202 by evanescent field coupling. The semiconductor laser element 200 further includes an output waveguide 206 optically coupled to the second ring resonator 204.

FIG. 2B is a side cross-sectional view taken along a line IIB-IIB of the semiconductor laser element 200 of FIG. 2A. The first ring resonator 202 comprises a first semiconductor stack 220 that includes a first n-side semiconductor layer 222, a first p-side semiconductor layer 224 and a first active layer 226 between the first n-side semiconductor layer 222 and the p-side semiconductor layer 224. The second ring resonator 204 comprises a second semiconductor stack 230 that includes a second n-side semiconductor layer 232, a second p-side semiconductor layer 234 and a second active layer 326 between the second n-side semiconductor layer 232 and the second p-side semiconductor layer 234. The output waveguide 206 comprises a third semiconductor stack 240 that includes a third n-side semiconductor layer 242, a third p-side semiconductor layer 244 and a third active layer 246 between the third n-side semiconductor 242 layer and the third p-side semiconductor layer 244.

In some embodiments, the first ring resonator 202 connects to the second ring resonator 204 by the n-side semiconductor layers. In other words, a part of the first n-side semiconductor layer 222 and a part of the second n-side semiconductor layer 232 may be continuously connected. Similarly, the second ring resonator 204 may connect to the output waveguide 206 by the n-side semiconductor layer. In other words, a part of the second n-side semiconductor layer 232 and a part of the third n-side semiconductor layer 242 may be continuously connected. In some embodiments, the first ring resonator 202, the second ring resonator 204, and the output waveguide 206 may be monolithically integrated on the same substrate, as in shown in FIG. 2B by substrate 250.

As used herein, the term “first n-side semiconductor layer”, “second n-side semiconductor layer”, “third n-side semiconductor layer” is also referred to simply as the term “n-side semiconductor layer”. As used herein, the term “first p-side semiconductor layer”, “second p-side semiconductor layer”, “third p-side semiconductor layer” is also referred to simply as the term “p-side semiconductor layer”. As used herein, the term “first active layer”, “second active layer”, “third active layer” is also referred to simply as the term “active layer”.

Referring further to FIG. 2B, an upper surface of the first active layer 226 and an upper surface of the second active layer 236 are coplanar. Thus, the first ring resonator 202 can be strongly optically coupled to the second ring resonator 204. An upper surface of the third active layer 246 of the output waveguide 206 is coplanar with an upper surface of the second active layer 236 of the second ring resonator 204. Thus, the output waveguide 206 can be strongly optically coupled to the second resonator 204. Each semiconductor stack may be made of, for example, Group III-V compound semiconductor or Group II-VI compound semiconductor. Each semiconductor stack made of Group III-V compound semiconductor may be made of, for example, a nitride-based semiconductor such as InN, AlN, GaN, InGaN, AlGaN, InGaAlN. In some embodiments, the semiconductor stack 220 of the first ring resonator 202 and the semiconductor stack 230 of the second ring resonator 204 are made of the same materials. In some embodiments, the semiconductor stack 240 of the output waveguide 206 and the semiconductor stack 230 of the second ring resonator 204 are made of the same materials. In some embodiments, the semiconductor stacks of the first ring resonator 202, the second ring resonator 204, and the output waveguide 206 are made of the same materials. In some embodiments, the active layer 226 of the first ring resonator 202 and the active layer 236 of the second ring resonator 204 are formed of the same materials. In some embodiments, the active layer 236 of the second ring resonator 202 and the active layer 246 of the output waveguide 206 are formed of the same materials. In some embodiments, specifically the active layers of the first ring resonator 202, the second ring resonator 204, and the output waveguide 206 are made of the same materials.

In some embodiments, both the first ring resonator 202 and the second ring resonator 204 are not doped with any rare earth elements. Rare earth elements include, for example, Erbium (Er), Praseodymium (Pr), Europium (Eu), and Neodymium (Nd) and so on. A peak wavelength of light emitted by the second ring resonator 204 can be the same as a peak wavelength of light emitted by the first ring resonator 202. When acting as a MOPA, the semiconductor laser element 200 can amplify high quality light such as a single-mode light, and the wavelength of light outputted from the semiconductor laser element 200 can be variable by changing a pitch of the diffraction grating.

The first ring resonator 202 includes one or more linear portions 208 and one or more curved portions 210. As shown in FIG. 2A, the first ring resonator 202 is a rectangular ring resonator formed of alternating linear portions 208 and curved portions 210. In the present application, the term “rectangular” includes shapes having rounded corners. The first ring resonator 202 includes four linear portions 208 and four curved portions 210. The linear portions 208 are substantially linear (e.g., follow a straight line) and define a length L₁, measured from one end of the linear portion 208 to the other end of the linear portion 208. In some embodiments, the length L₁ of the linear portion 208 is in a range of 0.01 μm to 20 μm, preferably 5 μm to 15 μm. The linear portions 208 are formed of a uniform waveguide 212, with no diffraction grating. The linear portions 208 have a lateral thickness, which may be the same as the lateral thickness T₁ described with respect to FIG. 1A. The curved portions 210 are located between, and couple with, the linear portions 208. The curved portions 210 are formed of a DFB waveguide 214, which includes a diffraction grating. Similar to the DFB ring resonator 120, the DFB waveguides 214 of the first ring resonator 202 allow for the first ring resonator 202 to cause single-mode lasing. The curved portions 210 have a maximum lateral thickness, which may be the same lateral thickness T₂ described with respect to FIG. 1C.

In some embodiments, the first ring resonator 202 includes exactly four linear portions 208 and exactly four curved portions 210. The diffraction grating may be located on only one of (i) all of the four linear portions 208 or (ii) all of the four curved portions 210. The diffraction grating can induce single-mode lasing, in which the single mode matches the diffraction gating pitch.

The second ring resonator 204 is a rectangular ring resonator that has substantially the same general shape as the first ring resonator 202. In some embodiments, the shapes of the first ring resonator 202 and the second ring resonator 204 are different. However, it is preferable that the shape of the first ring resonator 202 and shape of the second ring resonator 204 be substantially the same. The second ring resonator 204 includes four linear portions 208 and four curved portions 210. The entirety of the second ring resonator 204 is formed of uniform waveguides 212, with no diffraction grating. The lateral thickness of the uniform waveguides 212 of the second ring resonator 204 may be the same as the lateral thickness T₁ of the uniform waveguides 212 of the first ring resonator 202.

The second ring resonator 204 may amplify the single-mode light emitted by the first ring resonator 202. The peak wavelength of the light emitted by the second ring resonator 204 is the same as the peak wavelength of light emitted by the first ring resonator 202 because the semiconductor laser element 200 acts as an MOPA. When acting as a MOPA, if the semiconductor laser element 200 induces single-mode lasing, the wavelengths of the light emitted by the first ring resonator 202 and the second ring resonator 204 are the same. Light produced from the semiconductor laser element 200 can be extracted by a grating coupler introduced into the first ring resonator 202 or second ring resonator 204, or by the output waveguide 206. In the MOPA, the first ring resonator 202 may be considered to be a master oscillator and the second ring resonator 204 may be considered to be a power amplifier. Alternatively, the second ring resonator 204 may be considered a master oscillator and the first ring resonator 202 may be considered a power amplifier. Amplification is possible because of the second ring resonator 204 and the first ring resonator 202 being optically coupled at a coupled region 216, which corresponds to the linear portions 208 of the first ring resonator 202 and the second ring resonator 204. The linear portions 208 of the first ring resonator 202 and the second ring resonator 204 may be substantially parallel. A distance between the first ring resonator 202 and the second ring resonator 204 may be at a minimum at one of the linear portions 208. The distance between the first ring resonator 202 and the second ring resonator 204 may be kept constant at one of the linear portions 208. Thus, the first ring resonator 202 can be stably optically coupled to the second ring resonator 204. The first ring resonator 202 and the second ring resonator 204 are placed at a distance such that the first ring resonator 202 and the second ring resonator 204 are optically coupled by evanescent field coupling. Therefore, single mode light generated by the first ring resonator 202 is output to the second ring resonator 204, and the second ring resonator amplifies the single mode light. The distance between the first ring resonator 202 and the second ring resonator 204 is within the length of wavelength of light that the first ring resonator 202 emits. The distance may be in a range of 10 nm to 400 nm, and preferably in a range of 10 nm to 100 nm. Thus, the first ring resonator 202 can be strongly optically coupled to the second ring resonator 204. In some embodiments, the distance is 30 nm. Light from the second ring resonator 204 may return to the first ring resonator 202. However, the system maintains stability, as the second ring resonator 204 and the first ring resonator 202 oscillate at the same frequency.

The output waveguide 206 is optically coupled to the second ring resonator 204 by evanescent field coupling. Therefore, the output waveguide 206 can receive the single-mode light that has been amplified by the second ring resonator 204. The output waveguide 206 is formed of a uniform waveguide 212, with no diffraction grating. The output waveguide 206 may be linear or may include curves (e.g., bends) to direct light toward a target location. The output waveguide 206 is optically coupled to the second ring resonator 204 at a coupled region 216. The coupled region 216 corresponds to a linear portion 208 of the second ring resonator. The output waveguide 206 directs the amplified single-mode light from the second ring resonator 204 towards a target location. In some embodiments, an upper surface of an active layer of the output waveguide 206 is coplanar with an upper surface of the active layer of the second ring resonator 204. Thus, the output waveguide 206 is strongly optically coupled to the second ring resonator 204 by evanescent field coupling.

In some embodiments, the semiconductor laser element 200 includes the first ring resonator 202 and the second ring resonator 204 without the output waveguide 206. In some embodiments, the semiconductor laser element 200 includes additional ring resonator(s). The additional ring resonators may or may not include diffraction grating. For example, the semiconductor laser element 200 may be included in a topological insulator laser that is two-dimensional ring array arranged with specific rules. By making at least one of the rings on the array periphery the first ring resonator 202, the topological lasing mode can be locked to the wavelength of the resonator 202.

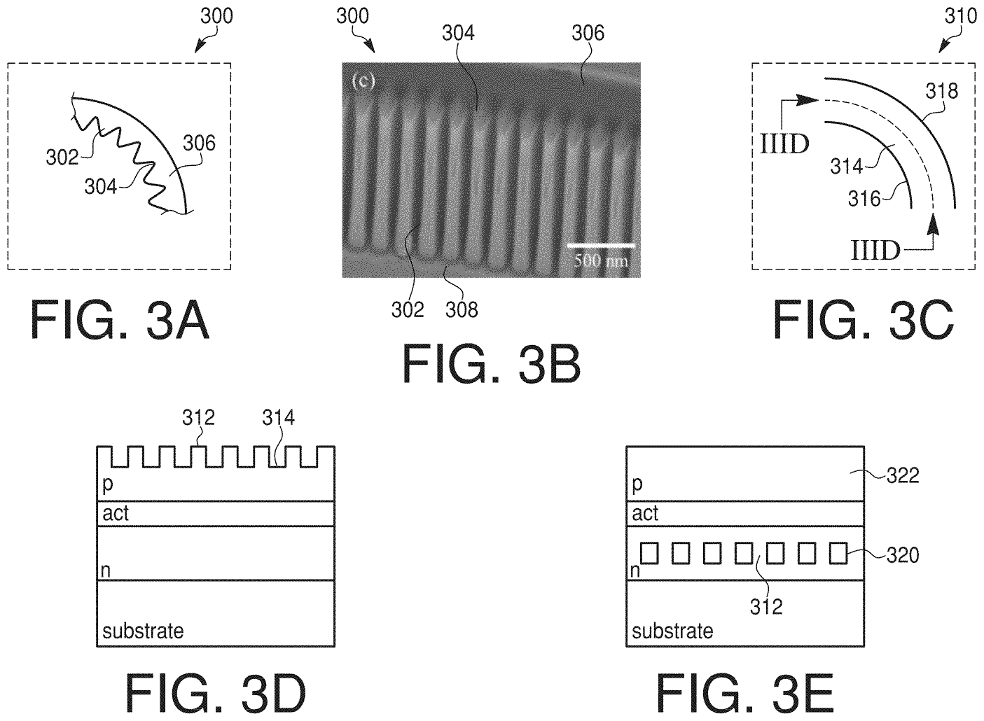

Referring generally to FIGS. 3A-E, various views of various diffraction gratings on DFB waveguides are shown, according to exemplary embodiments. The diffraction gratings are the portions of a DFB waveguide that cause single-mode lasing. The diffraction grating width, height, etc. may be specifically configured for the wavelength the waveguide is configured to emit.

FIG. 3A is a top view of a DFB waveguide 300 corresponding to the curved portion 210 of the first ring resonator 202 of the FIG. 2A. FIG. 3B is a close-up view of view of the diffraction grating 302 on the DFB waveguide 300 corresponding to the curved portion 210 of first ring resonator 202 of FIG. 2A. FIG. 3B depicts a DFB waveguide 300 that includes a diffraction grating 302 along a lateral surface 304. The diffraction grating 302 has a periodic structure corresponding to the wavelength desired in the semiconductor laser element 200. The pitch of the diffraction grating 302 may be in a range of 50 nm to 5000 nm. and preferably in a range of 100 nm to 200 nm. The diffraction grating 302 may be disposed on at least one of an inner lateral surface 304 of the first ring resonator 202 and an outer lateral surface of the first ring resonator 202. Thus, the diffraction grating 302 can induce single-mode lasing, in which the single mode matches the pitch of the diffraction gating 302. In FIG. 3B, the lateral surface 304 has the diffraction grating 302 is the inner lateral surface, but in other embodiments, the diffraction grating may be located on an outer lateral surface of the DFB waveguide 300.

The diffraction grating 302 may extend entirely from an upper surface 306 to a lower surface 308 of the DFB waveguide 300, or may extend only partially between the upper surface 306 and the lower surface 308. In some embodiments, specifically the diffraction grating 302 may extend only partially between an upper surface and an lower surface of the p-side semiconductor layer 224, or an upper surface and an lower surface of the n-side semiconductor layer 222.

In some embodiments, a DFB waveguide has a diffraction grating on an upper surface of the DFB waveguide. FIG. 3C is a top view of a DFB waveguide 310 corresponding to a curved portion of a first ring resonator of the semiconductor laser element of FIG. 2A. FIG. 3D is an exemplary side cross-sectional view taken along a line IIID-IIID of the DFB waveguide 310 of the FIG. 3C. The diffraction grating 312 is disposed on an upper surface 314 of the DFB waveguide 310. The diffraction grating 312 extends across the entirety of the lateral thickness of the upper surface 314 from an inner lateral surface 316 of the DFB waveguide 310 to an outer lateral surface 318 of the DFB waveguide 310.

In some embodiments, the DFB waveguide 310 has an embedded diffraction grating. FIG. 3E is another exemplary side cross-sectional view taken along a line IIID-IIID of waveguide 310 of the FIG. 3C. The diffraction grating 312 is embedded in the first ring resonator 202. In some embodiments, the n-side semiconductor layer 320 may have the diffraction grating 312 and/or the p-side semiconductor layer 322 may have the diffraction grating 312. In some embodiments, a waveguide may include any combination of lateral surface diffraction grating, upper surface diffraction grating, and/or embedded diffraction grating.

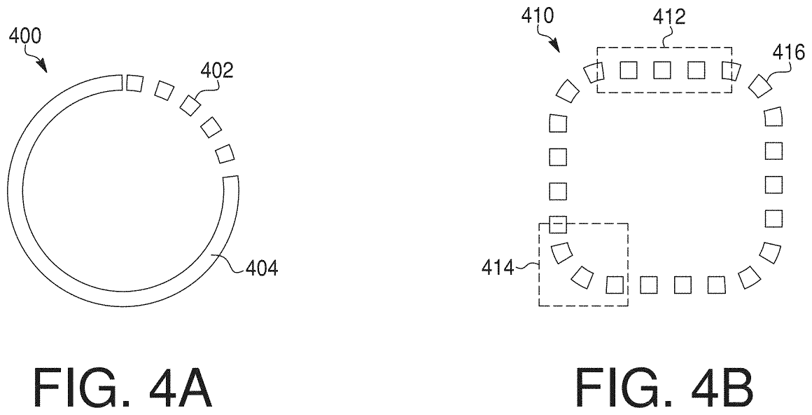

FIGS. 4A-B are top views of alternate embodiments of ring resonators, according to exemplary embodiments. R₁ng resonators, such as the first ring resonator 202 and the second ring resonator 204, of a semiconductor laser element, such as the semiconductor laser element 200, may be any shape and size. For example, the ring resonators may be circular or polygonal (triangular, rectangular, etc.). While the second ring resonator 204 is formed of a uniform waveguide, the first ring resonator 202 may include a diffraction grating that is only in a portion or portions of the first ring resonator 202, or a diffraction grating that is included along the entirety of the waveguide. The diffraction grating may be included on at least one of the inner lateral surface, outer lateral surface, upper surface, and/or embedded in the waveguide. For example, the diffraction grating may be included along the entirety of the inner lateral surface or the outer lateral surface of the first ring resonator 202.

Referring now to FIG. 4A, a circular DFB resonator 400 with a partial diffraction grating is shown, according to a particular embodiment. The DFB resonator 400 is a circular ring resonator and includes a diffraction grating 402 in only a portion of the DFB resonator 400. The remainder of the DFB resonator 400 is a uniform waveguide 404, which is substantially similar to the uniform waveguide 102. The diffraction grating 402 may only be in a portion of the circumference of the DFB resonator 400 in a range of 5% to 100% of the total circumference. The diffraction grating 402 may be contiguous (e.g., continuous) or may be disposed around the circumference with uniform waveguide 404 sections between.

Referring now to FIG. 4B, a rectangular DFB resonator 410 with a diffraction grating is shown, according to a particular embodiment. The DFB resonator 410 is a rectangular ring resonator and includes four linear portions 412 and four curved portions 414. The DFB resonator 410 includes a diffraction grating 416 along the entire perimeter of the DFB resonator 410. In some embodiments, the diffraction grating 416 may appears in only the curved portion 414 or only in the linear portions 412. In some embodiments, the diffraction grating 416 may be included in an asymmetric configuration. For example, only one of the four curved portions 414 may include the diffraction grating 416.

### Experimental Results

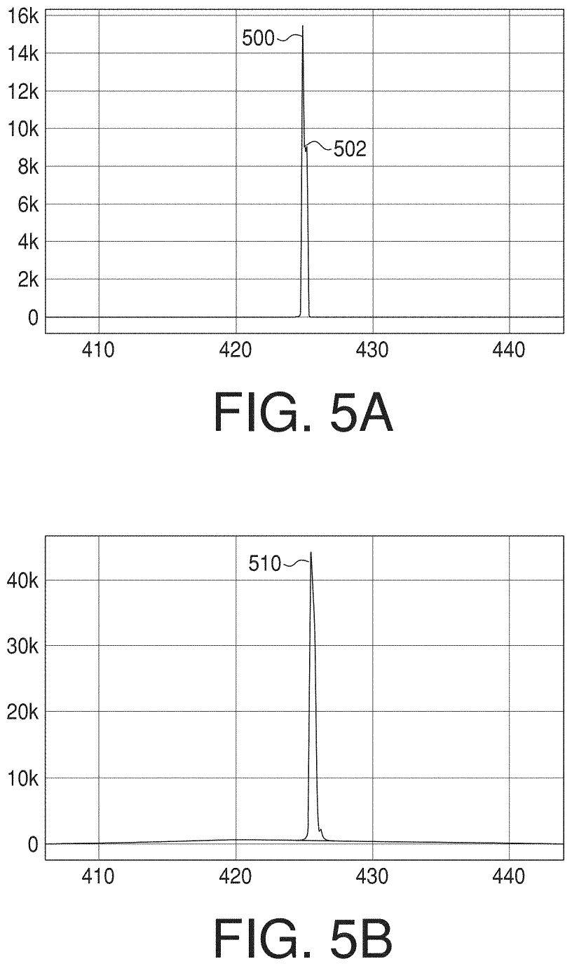

FIG. 5A shows a spectrum graph, at a pump power of 47.2 μW, of a DFB ring resonator, such as the first ring resonator 202, which has a lasing threshold pump power of 11.6 μW. The spectrum graph shows that, at the pump power of 47.2 μW, the first ring resonator 202 produces a first peak 500 and a second peak 502, thus deviating from the intended single-mode lasing. In this device, single-mode lasing is maintained at pump powers up to about four times the lasing threshold (e.g., lowest excitation level at which a laser outputs mostly stimulated emissions).

FIG. 5B shows a spectrum graph, at a pump power of 95.9 μW, of a semiconductor laser element, such as semiconductor laser element 200, having optically coupled ring resonators according to an embodiment of the invention. The spectrum graph shows that, at the pump power of 95.9 μW, the semiconductor laser element 200 produces a single peak 510, demonstrating that single-mode lasing is maintained. In this device, single-mode lasing is maintained at pump powers at least 9 times higher than the lasing threshold, in the longitudinal mode. Thus, the semiconductor laser element 200 allows for high brightness and a high power single mode lasing.

### Methods of Manufacturing Semiconductor Laser Elements

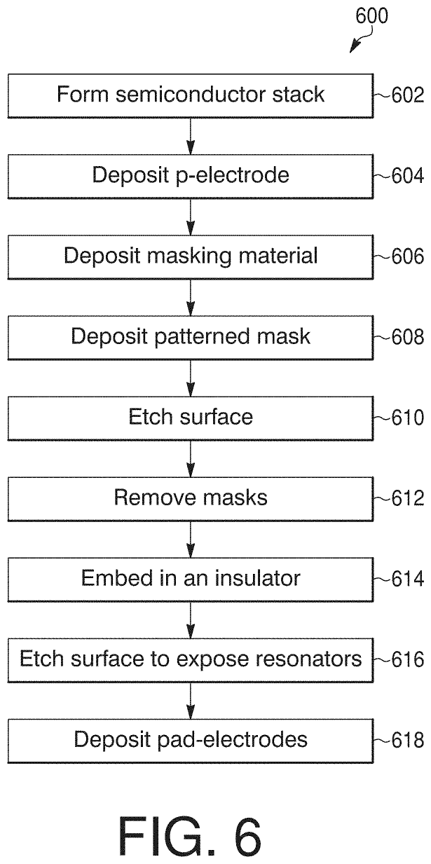

Referring now to FIG. 6, a flow diagram of a method 600 of forming a semiconductor laser element is shown, according to an exemplary embodiment. The formed semiconductor laser element produces amplified single-mode lasing.

Steps of the method 600 including electrodes may be optional in case that the semiconductor laser element is driven by optical pumping. During optical pumping, the semiconductor laser element is irradiated by auxiliary light source whose wavelength is shorter than the emission wavelength of the semiconductor laser element.

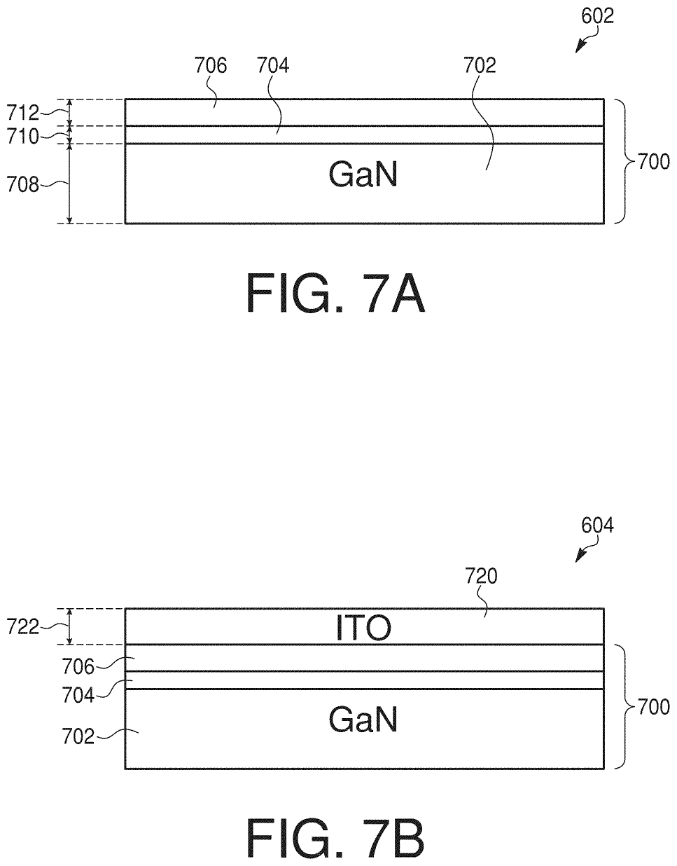

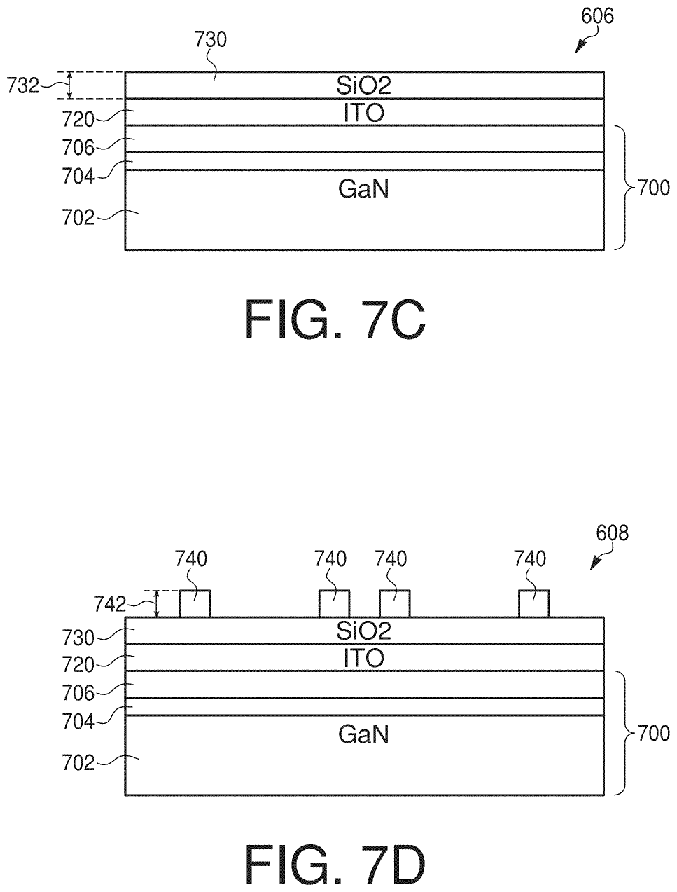

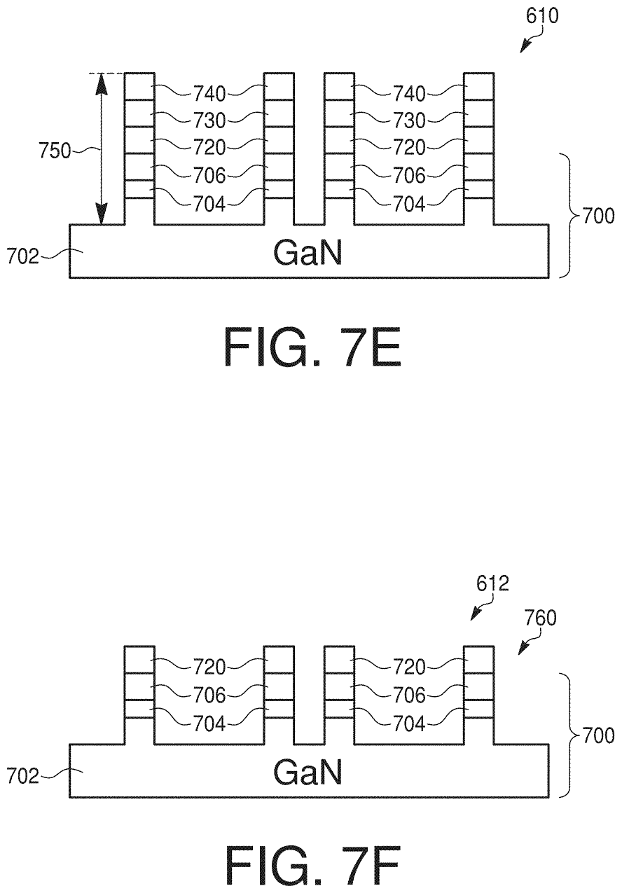

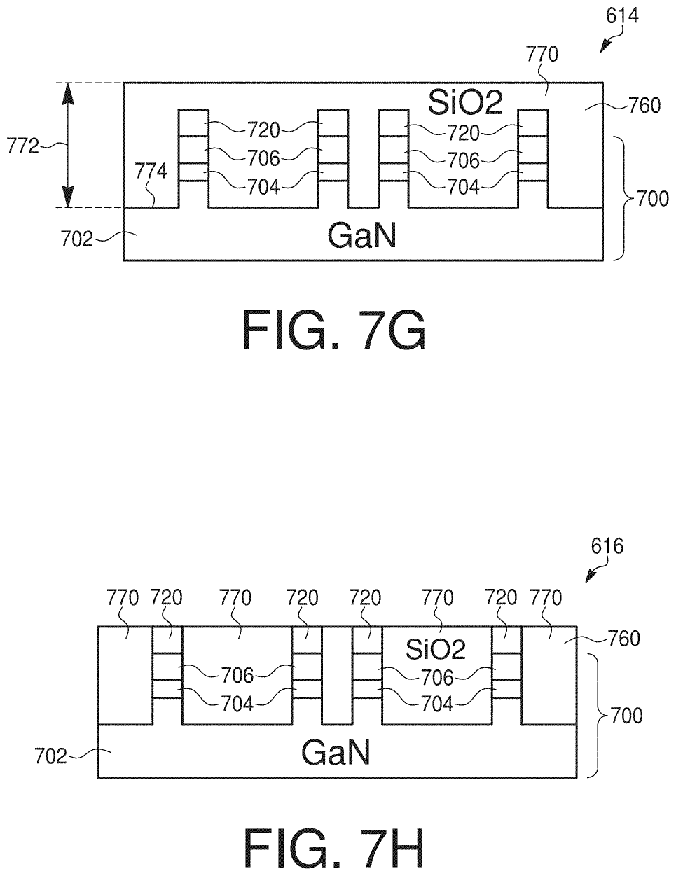

At step 602, a semiconductor stack is formed. The semiconductor stack includes an n-side semiconductor layer, a p-side semiconductor layer, and an active layer located between the n-side semiconductor layer and the p-side semiconductor layer. Exemplary results of step 602 are shown in and described in reference to FIG. 7A.

At step 604, a p-electrode layer (also referred to as the “p-electrode”) is deposited on the p-side semiconductor layer of the semiconductor stack formed in step 602. The p-electrode serves as a conductive coating for the semiconductor stack. In some embodiments, the p-electrode layer is deposited to a predetermined height. Exemplary results of step 604 are shown in and described in reference to FIG. 7B.

At step 606, a masking material is deposited on the p-electrode layer formed during step 604. The masking material provides protection during etching and provides a surface for an etching mask to adhere. In some embodiments, the masking material may be deposited to a predetermined height. Exemplary results of step 606 are shown in and described in reference to FIG. 7C.

At step 608, a patterned mask is deposited on the masking material deposited in step 606. The patterned mask shields the portions of the active layer that are to become the semiconductor laser element from being removed during etching in step 610. The patterned mask may include portions that include a periodic structure to form a diffraction grating on portions of the semiconductor laser element. Exemplary results of step 608 are shown in and described in reference to FIG. 7D.

At step 610, the surface is etched to form a semiconductor laser element. Etching removes portions of the masking material, the p-electrode layer, the p-side semiconductor layer, the active layer, and a portion of the n-side semiconductor layer in areas that are not covered by the patterned mask deposited in step 608. Thus, etching forms a first ring resonator corresponding to a first ring portion of the patterned mask and a second ring resonator corresponding to a second ring portion of the patterned mask. Etching also forms a diffraction grating on the first ring resonator corresponding to the periodic structure of the patterned mask. Exemplary results of step 610 are shown in and described in reference to FIG. 7E.

At step 612, the patterned mask and the masking material remaining on the semiconductor stack is removed. Removing is achieved by a etching process, which is appropriate to the removed material and may include a dry etching process or a wet etching process. Removing the patterned mask and the masking material leaves a semiconductor laser element including the p-electrode layer, the p-side semiconductor layer, the active layer, and the n-side semiconductor layer formed into a first resonator ring and a second resonator ring. The first resonator ring including a diffraction grating. Exemplary results of step 612 are shown in and described in reference to FIG. 7F.

At step 614, the semiconductor laser element is embedded into an insulator. The insulator insulates the semiconductor laser element from other components of the semiconductor laser element (and other components of a laser system) and ensure a proper current flow from p-side semiconductor to n-side semiconductor. Exemplary results of step 614 are shown in and described in reference to FIG. 7G.

At step 616, the surface of the insulator is etched to reveal the semiconductor laser element. The etch depth may be configured to a predetermined distance or etching may continue until the semiconductor laser element is exposed. Exemplary results of step 616 are shown in and described in reference to FIG. 7H.

At step 618, pad electrodes are applied to form the semiconductor laser element via an evaporation process, a sputtering process, etc. A positive pad electrode is applied to the surface including the exposed semiconductor laser element and a negative pad electrode is applied to the n-side semiconductor layer. The resulting semiconductor laser element embedded in an insulator with pad electrodes may be used in a semiconductor laser system. Exemplary results of step 618 are shown in and described in reference to FIG. 7I.

In some embodiments, the method 600 may include additional steps such as surface preparation steps (e.g., scribing, cleaning, etc.). In some embodiments, the additional steps may include forming additional layers.

Referring generally to FIGS. 7A-7I, depictions of the steps of the method 600 of FIG. 6 are shown, according to exemplary embodiments. The semiconductor laser element produced in FIGS. 7A-7I is an exemplary semiconductor laser element produced based on an embodiment of the method 600. Various other semiconductor laser elements may be formed by the method 600 that are not depicted in the figures.

Referring now to FIG. 7A, a depiction of the result of the step 602 of FIG. 6 is shown, according to an exemplary embodiment. FIG. 7A depicts a semiconductor stack 700 formed of layered epitaxial films. In some embodiments, the semiconductor stack 700 comprises a semiconductor stack made of a group III-V semiconductor material or a group II-VI semiconductor material. In some embodiments, the semiconductor stack 700 is formed via chemical vapor deposition (CVD) (e.g., atmospheric pressure CVD (APCVD), metal organic CVD (MOCVD), etc.) or, physical vapor deposition (PVD) (e.g., molecular beam epitaxy (MBE), sputtering, etc.). In the shown embodiment, the semiconductor stack 700 comprises gallium nitride (GaN). In some embodiments, the semiconductor stack 700 is manufactured by MOCVD in a pressure and temperature adjustable chamber. Each nitride semiconductor layer can be formed by introducing a carrier gas and a source gas into the chamber. For the carrier gas, hydrogen (H₂) or nitrogen (N₂) gas can be used. Ammonia (NH₃) gas can be used as a nitrogen source. Trimethylgallium (TMG) or triethylgallium (TEG) gas can be used as a Ga source gas. Trimethylindium (TMI) gas can be used as an In source gas. Trimethylaluminum (TMA) gas can be used as an Al source gas. Monosilane (SiH₄) gas can be used as a Si source gas. Bis(cyclopentadienyl)magnesium (Cp₂Mg) gas can be used as a Mg source gas.

The semiconductor stack 700 comprises an n-side semiconductor layer 702, an active layer 704, and a p-side semiconductor layer 706. The active layer 704 is located between the n-side semiconductor layer 702 and the p-side semiconductor layer 706. The n-side semiconductor layer 702 has an n-side layer height 708. The active layer 704 has an active layer height 710. The p-side semiconductor layer 706 has a p-side layer height 712. The n-side layer height 708, the active layer height 710, and the p-side layer height 712 may be specifically configured for the application of the semiconductor laser element being formed by the method 600, or may be configured to fit a constraint such as height, weight, etc. of the semiconductor laser element. In some embodiments, the active layer 704 is formed such that a lower and/or upper surface of the active layer forms a plane. This allows for formed semiconductor laser elements to include components with coplanar active layer surfaces. For example, an upper surface of an active layer of the first ring resonator 202 and the upper surface of an active layer of the second ring resonator 204 may be coplanar and/or an upper surface of an active surface of the output waveguide 206 and the upper surface of the second ring resonator 204 may be coplanar. In some embodiments, the same active layer material is used in both resonators of a semiconductor laser element.

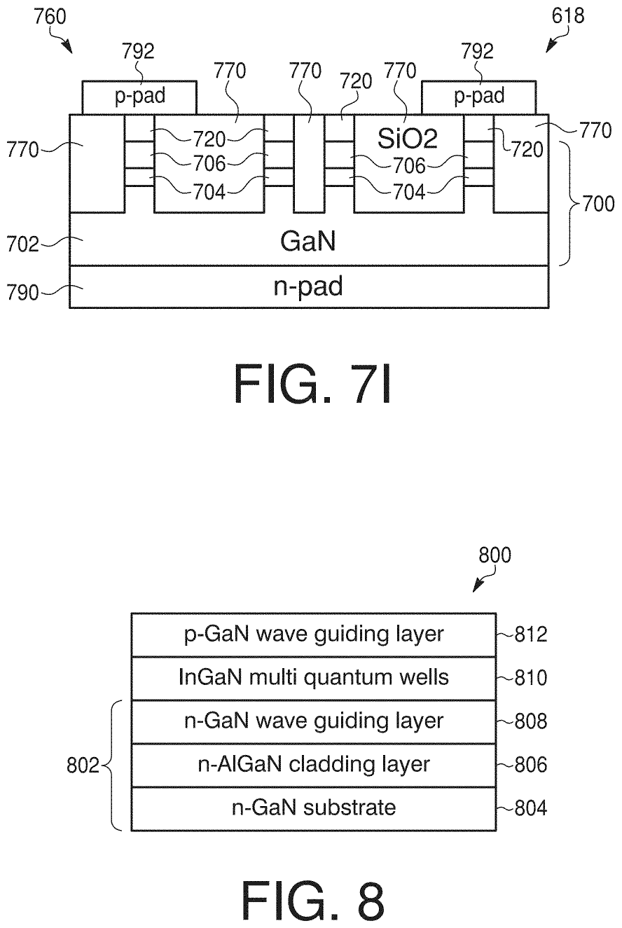

FIG. 8 shows an alternate example of a semiconductor stack 800 that may be used as the semiconductor stack 700 shown in FIG. 7A. The semiconductor stack 800 includes an n-side semiconductor layer 802. The n-side semiconductor layer 802 includes a substrate 804, an n-side cladding layer 806 and an n-side wave guiding layer 808. The semiconductor stack 800 further includes an active layer 810 and a p-side semiconductor layer 812. The p-side semiconductor layer 812 may include a p-side wave guiding layer and a p-side cladding layer. In the embodiment depicted, the substrate 804 comprises n-type GaN and is located below the n-side cladding layer 806. The n-side cladding layer 806 comprises n-type AlGaN, is 2400 nm thick, and is located below the n-side wave guiding layer 808. The n-side wave guiding layer 808 comprises GaN, is 170 nm thick, and is located below the active layer 810. The active layer 810 has a multiple quantum well structure including InGaN well layers, is 136 nm thick, and is located below the p-side semiconductor layer 812. The p-side semiconductor layer 812 comprises a GaN wave guiding layer and is 170 nm thick.

Referring now to FIG. 7B, a depiction of the result of the step 604 of FIG. 6 is shown, according to an exemplary embodiment. FIG. 7B depicts a p-electrode layer 720 deposited on the p-side semiconductor layer 706 of the semiconductor stack 700. In some embodiments, the p-electrode layer 720 is formed via sputtering. In the embodiment depicted, p-electrode layer 720 comprises a transparent electrode such as indium tin oxide (ITO) and aluminum-doped zinc oxide (AZO), or metal electrode including Ti, Ni, Cr, Al, Au, Rh or Pt. In some embodiment, the p-electrode layer 720 comprises a conductive oxide such as ITO, which is preferred for etching. The p-electrode layer 720 has a p-electrode layer height 722. The p-electrode layer height 722 may be configured for the application of the semiconductor laser element, or may be configured to fit a constraint.

Referring now to FIG. 7C, a depiction of the result of the step 606 of FIG. 6 is shown, according to an exemplary embodiment. FIG. 7C depicts a masking material 730, formed in step 606, on the p-electrode layer 720. In some embodiments, the masking material 730 may be deposited via CVD. In some embodiments, the masking material 730 is an insulator film. In some embodiments, the masking material 730 may be SiO₂, SiN or AlN. The masking material 730 may be formed to a masking material height 732. The masking material height 732 may be configured to provide sufficient protection (e.g., etching only etches desired portions) and sufficient adhesion (e.g., mask does not come off the masking material 730 during etching) for the patterned mask to adhere.

Referring now to FIG. 7D, a depiction of the result of step 608 of FIG. 6 is shown, according to an exemplary embodiment. FIG. 7 depicts a patterned mask 740, formed in step 608, deposited on the masking material 730. In some embodiments, the patterned mask may be deposited on the n-side semiconductor layer 702 or the p-side semiconductor layer 706 of the semiconductor stack 700. The patterned mask 740 may be formed to a masking material height 742. The patterned mask 740 is deposited on the masking material 730 such that the etching step 610 produces a semiconductor laser element. The masking material height 742 may be configured such that the patterned mask 740 provides sufficient protection (e.g., etching only etches desired portions) during etching at step 610. The patterned mask may comprise a negative tone resist. In some embodiments, the patterned mask is applied via electron beam lithography.

The shape of the patterned mask 740 may include at least a first ring-shaped portion and a second ring-shaped portion corresponding to the shape of the semiconductor laser element in the formed semiconductor laser element. For example, the patterned mask may correspond to the shape of the first ring resonator 202 and the second ring resonator 204. The patterned mask 740 may also include a periodic structure. The periodic structure may be located at an inner lateral surface or an outer lateral surface of the first ring-shaped portion. The shape (e.g., amplitude, period, etc.) of the periodic structure corresponds to the wavelength desired in the semiconductor laser element.

Referring now to FIG. 7E, a depiction the result of the step 610 of FIG. 6 is shown, according to an exemplary embodiment. FIG. 7E depicts the results of the etching step 610. Etching removes portions of the masking material 730, the p-electrode layer 720, the p-side semiconductor layer 706, the active layer 704, and the n-side semiconductor layer 702. Etching does not remove material under the patterned mask 740. The surface may be etched to an etch depth 750. The etch depth 750 is configured such that only a portion of the n-side semiconductor layer 702 is exposed or to avoid etching into a substrate. In some embodiments, the etch depth 750 may be a predefined depth or etching may continue until after the semiconductor laser element is formed. In some embodiments, the etch depth 750 is 1.5 μm (micrometers).

In some embodiments, the etching may be dry etching, wherein the surface is exposed to ions that dislodge portions of material from the exposed (e.g., unmasked) surface. In some embodiments, etching may be via reactive ion etching. A different gas may be used for etching depending on the material being etched. For example, CHF₃ and O₂ may be used to etch the masking layer and Cl₂ and SiCl₄ may be used to etch the layers of the semiconductor stack. Etching may operate on a number of parameters, such as flow rate (e.g., flow rate of the ions), temperature, ambient pressure, duration, and the like. In some embodiments, the pressure during etching is in a range of 0.1 Pa to 5 Pa.

Referring now to FIG. 7F, a depiction of the result of the step 612 of FIG. 6 is shown, according to an exemplary embodiment. FIG. 7F depicts a semiconductor laser element 760 including the p-electrode layer 720 on the semiconductor stack 700, as the masking material 730 and the patterned mask 740 are removed in step 612.

Referring now to FIG. 7G, a depiction of the result of step 614 of FIG. 6 is shown, according to an exemplary embodiment. FIG. 7G depicts an insulator 770, formed in step 614, embedding the semiconductor laser element 760. In the shown embodiment, the insulator 770 may extend away from a lower etched surface 774 of the n-side semiconductor layer 702 by an insulator height 772. The insulator height 772 is configured so that the insulator 770 may completely encase the semiconductor laser element 760. In the depicted embodiment, the insulator can be SiO₂, SiN, or AlN.

Referring now to FIG. 7H, a depiction of the result of the step 616 of FIG. 6 is shown, according to an exemplary embodiment. FIG. 7H depicts an exposed p-electrode layer 720, as the insulator 770 has been removed. In some embodiments, the upper surface of the p-electrode layer 720 and the upper surface of the insulator 770 are coplanar. The etching used to expose the p-electrode layer may be reactive ion etching. In some embodiments, CHF₃ and O₂ may be used for etching.

Referring now to FIG. 7I, a depiction of the resulting semiconductor laser element 760 of the step 618 of FIG. 6 is shown, according to an exemplary embodiment. FIG. 7I depicts the n-pad electrode 790 and the p-pad electrode 792, as applied in step 618, to the semiconductor laser element 760. In the depicted embodiment, the p-pad electrode 792 is stacked on the insulator 770 and the p-electrode layer 720 and the n-pad electrode 790 is stacked below the n-side semiconductor layer 702. The configuration of the positive pad electrode and the negative pad electrode allows for charge to flow from the negative pad electrode to the positive pad electrode through the semiconductor laser element. In some embodiments, the positions of the positive pad electrode and the negative pad electrode may be switched depending on the orientation of the semiconductor stack 700. In some embodiments, the configuration of the semiconductor laser element and the pads of the semiconductor laser element might be to allow easier access to the pad electrodes (e.g., flip-chip configuration, controlled collapse chip connection, etc.).

According to one embodiment, a method of forming a semiconductor laser element includes the steps of forming a semiconductor stack that includes an n-side semiconductor layer, a p-side semiconductor layer, and an active layer located between the n-side semiconductor layer and the p-side semiconductor layer. The method further includes forming a mask on the semiconductor stack, wherein the mask includes a first ring-shaped portion and a second ring-shaped portion, wherein a periodic structure is located at an inner lateral surface or outer lateral surface of the first ring-shaped portion. The method further includes dry etching the semiconductor stack to form a first ring resonator corresponding to the first ring-shaped portion and a second ring resonator corresponding to the second ring-shaped portion, the first ring resonator comprising a diffraction grating corresponding to the periodic structure, wherein the dry etching is performed at a pressure in a range of 0.1 Pa to 5 Pa.

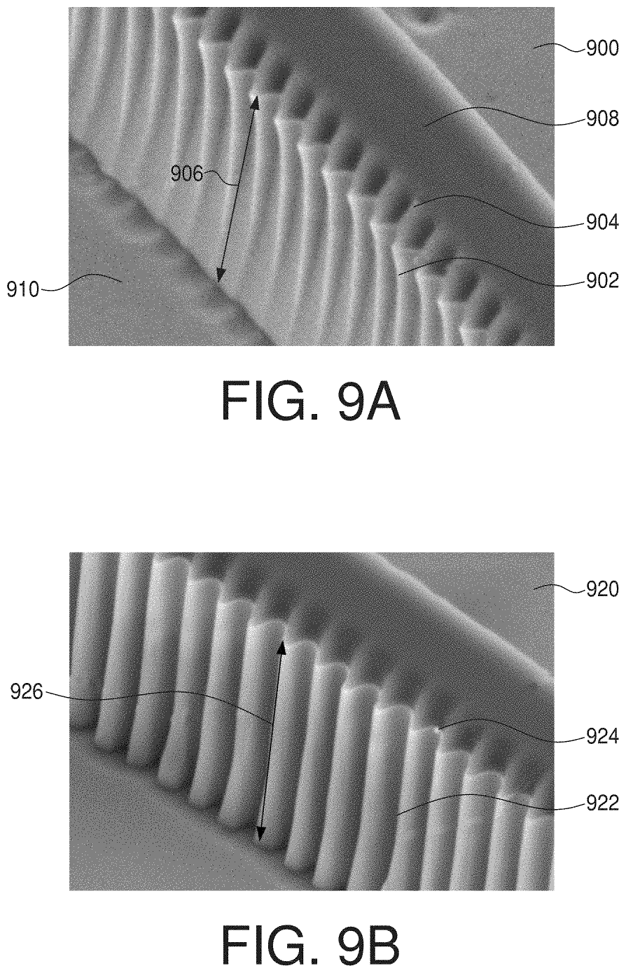

FIGS. 9A-B show close-up views of the effects of forming diffraction gratings under different pressures, according to exemplary embodiments. The diffraction gratings appear on a lateral surface of a waveguide and were formed by etching, as described in reference to step 610 of FIG. 6, under different pressures.

FIG. 9A shows a close-up view of a waveguide 900 including a diffraction grating 902 on a lateral surface 904. The diffraction grating 902 is formed under a pressure of 12 Pa. At this pressure, the diffraction grating 902 loses definition (e.g., desired shape) along a diffraction grating height 906 from an upper surface 908 to a lower surface 910. The loss of definition may be a result of etchant ricochet during etching which removes material that is not intended to be removed. The loss of definition may adversely affect the modes of light formed by the waveguide 900, which may correspond to additional modes being introduced beyond the intended single-mode.

FIG. 9B shows a close-up view of a waveguide 920 including a diffraction grating 922 on a lateral surface 924. The diffraction grating 922 is formed under a pressure of 0.5 Pa. At this pressure the formed diffraction grating 922 is substantially more uniform along the diffraction grating length 926 than the diffraction grating 902 of the waveguide 900. Thus, decreasing the ambient pressure during etching corresponds to a decrease in the amount of etchant ricochet and increases the fidelity of a diffraction grating. In some embodiments, pressures of 5 Pa or less result in higher fidelity diffraction gratings. More preferably, the pressures of 3 Pa or less produce even higher fidelity diffraction gratings. Even more preferably, pressures of 1 Pa or less produce even higher fidelity diffraction gratings.

### Other Embodiments

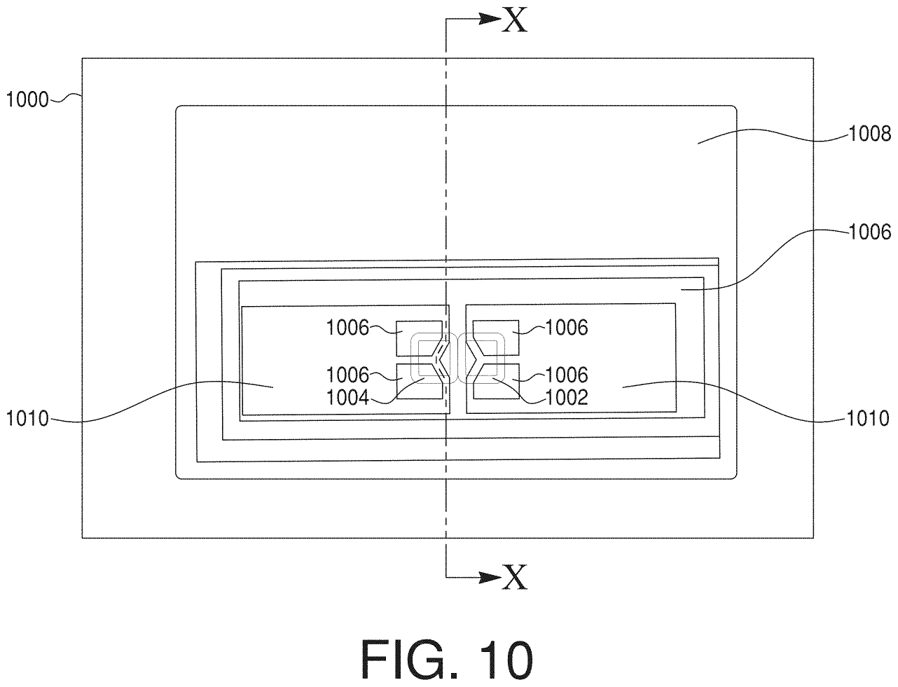

Referring now to FIG. 10, a top view of a semiconductor laser element 1000 is shown, according to another embodiment. The semiconductor laser element 1000 has a configuration in which both pad electrodes are located on the same side of the semiconductor laser element 1000. The semiconductor laser element 1000 includes a first ring resonator 1002, which is substantially similar to the first ring resonator 1002, and a second ring resonator 1004, which is substantially similar to the second ring resonator 1004. The first ring resonator 1002 and the second ring resonator 1004 are optically coupled and embedded in an insulator 1006, which is substantially similar to the insulator 770. The insulator further separates an n-pad electrode 1008, which is substantially similar to the n-pad electrode 790, and a p-pad electrode 1010, which is substantially similar to the p-pad electrode 792. Charge may flow from the n-pad electrode 1008 to the p-pad electrode 1010 through the semiconductor laser element.

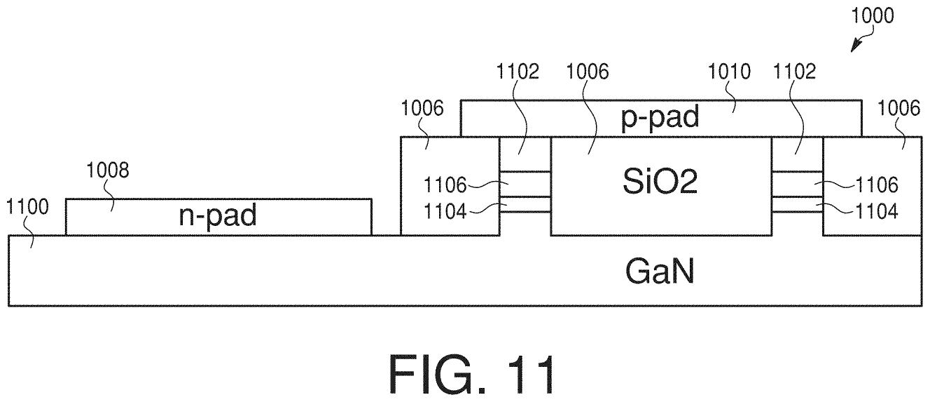

Referring now to FIG. 11, a cross-sectional view taken along a line X-X of the semiconductor laser element 1000 of FIG. 10 is shown. As seen in FIG. 11, the n-pad electrode 1008 is stacked on an n-side semiconductor layer 1100, which is substantially similar to the n-side semiconductor layer 702. The n-pad electrode 1008 is offset from the p-pad electrode 1010, which is stacked on the insulator 1006 and a p-electrode layer 1102, which is substantially similar to the p-electrode layer 720. The configuration of the semiconductor laser element 1000 allows for charge to flow from the n-pad electrode 1008 through the n-side semiconductor layer 1100, an active layer 1104 (which is substantially similar to the active layer 704), a p-side semiconductor layer 1106 (which is substantially similar to the p-side semiconductor layer 706), and the p-electrode layer 1102 to the p-pad electrode 1010, while allowing for the pad electrodes to be accessible from one side.

In some embodiments, p-pad electrode 1010 and n-pad electrode 1008 are separated by first ring resonator 1002 and the second ring resonator 1004. Electric current applied to the first ring resonator 1002 and electric current applied to the second ring resonator 1004 may independently be controlled. The magnitude of the electrical current density applied to the first ring resonator 1002 is lower than the magnitude of the electrical current density applied to the second ring resonator 1004. The second ring resonator 1004 can amplify and maintain the single-mode light of the longitudinal mode.

### Experimental Results

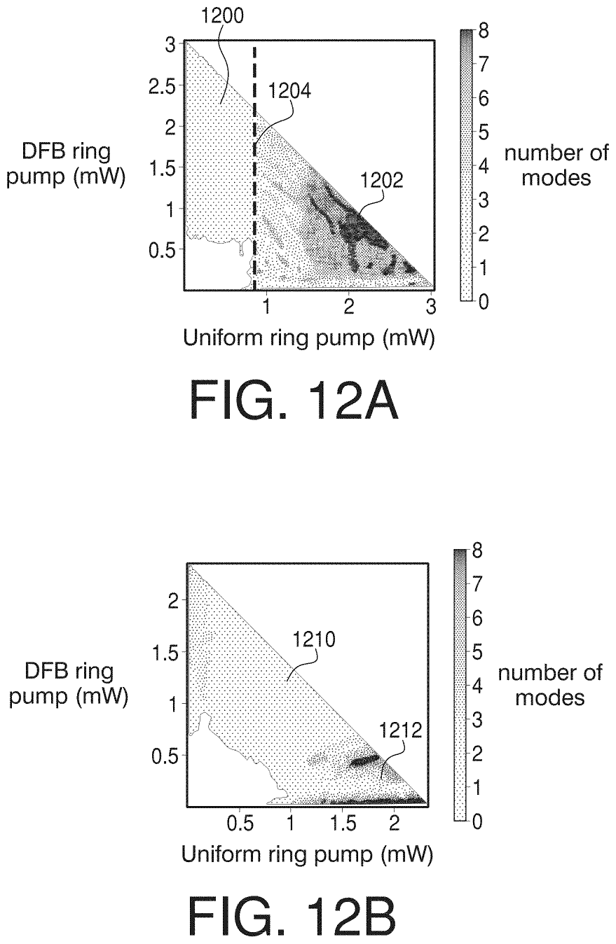

Referring generally to FIGS. 12A-B, lasing mode graphs of experimental results of a semiconductor laser element, such as semiconductor laser element 200, with different distances between ring resonators, such as the first ring resonator 202 and the second ring resonator 204, are shown, according to an exemplary embodiment. The semiconductor laser element is optically pumped by a 355 nm Nd:YAG solid state laser. The radiation from the samples is collected by an objective and coupled to an optical fiber connected to a spectrometer. To evaluate the mode stabilization effect of the semiconductor laser element, the spectrum is monitored while varying the pump intensity.

Referring now to FIG. 12A, a spectrum graph of a semiconductor laser element is shown. The two ring are separated by a distance of 500 nm, which is too far from one another to experience significant optical coupling. As seen in the spectrum graph, single-mode lasing 1200 and multi-mode lasing 1202 are both produced. However, the multi-mode lasing generally appears above a threshold 1204 which corresponds to a pumping power of the uniform ring resonator (corresponding to the second ring resonator 204) and is substantially independent of the pumping power of the DFB ring resonator (corresponding to the first ring resonator 202). The threshold 1204 indicates that there is no coupling between the two ring resonators and the ring resonators operate independently at a distance of 500 nm.

Referring now to FIG. 12B, a spectrum graph of a semiconductor laser element is shown. The two ring resonators are separated by a distance of 30 nm, which allows for optical coupling. As seen in the spectrum graph, the semiconductor laser element also causes single-mode lasing 1210 and multi-mode lasing 1212. However, the single-mode lasing is observed when the two ring resonators are simultaneously lasing. Thus, the DFB ring resonator forces single mode lasing in both ring resonator, locking the modes of the multi-mode high-power ring laser to the mode defined by the diffraction grating. In this configuration, the intensity can be increased considerably while retaining single-mode lasing of the longitudinal mode up to 11 times about the lasing threshold.

Moreover, for example, the present disclosure may have the following configurations.

(1) A semiconductor laser element comprising:
a first ring resonator comprising:
   a first semiconductor stack comprising a first n-side semiconductor layer, a first p-side semiconductor layer, and a first active layer located between the first n-side semiconductor layer and the first p-side semiconductor layer,
   wherein the first ring resonator comprises a diffraction grating; and
a second ring resonator optically coupled to the first ring resonator by evanescent field coupling, the second ring resonator comprising:
   a second semiconductor stack comprising a second n-side semiconductor layer, a second p-side semiconductor layer, and a second active layer located between the second n-side semiconductor layer and the second p-side semiconductor layer;
wherein a peak wavelength of light emitted by the second ring resonator is the same as a peak wavelength of light emitted by the first ring resonator.

(2) A semiconductor laser element comprising:
a first ring resonator comprising:
   a first semiconductor stack comprising a first n-side semiconductor layer, a first p-side semiconductor layer, and a first active layer located between the first n-side semiconductor layer and the first p-side semiconductor layer,
   wherein the first ring resonator comprises a diffraction grating; and
a second ring resonator optically coupled to the first ring resonator by evanescent field coupling, the second ring resonator comprising:
   a second semiconductor stack comprising a second n-side semiconductor layer, a second p-side semiconductor layer, and a second active layer located between the second n-side semiconductor layer and the second p-side semiconductor layer;
wherein the first ring resonator and the second ring resonator are not doped with any rare earth elements.

(3) The semiconductor laser element of (1) or (2), wherein the first active layer and the second active layer are formed of the same material.

(4) The semiconductor laser element of any one of (1) to (3), wherein an upper surface of the first active layer and an upper surface of the second active layer are coplanar.

(5) The semiconductor laser element of any one of (1) to (4), wherein the diffraction grating is disposed on at least one of an inner lateral surface the first ring resonator and an outer lateral surface of the first ring resonator.

(6) The semiconductor laser element of any one of (1) to (4), wherein the diffraction grating is disposed on an upper surface of the first ring resonator.

(7) The semiconductor laser element of any one of (1) to (4), wherein the diffraction grating is embedded in the first ring resonator.

(8) The semiconductor laser element of any one of (1) to (7), wherein:
the first ring resonator includes one or more linear portions and one or more curved portions, and
a distance between the first ring resonator and the second ring resonator is at a minimum at one of the one or more linear portions.

(9) The semiconductor laser element of (8), wherein the distance is in a range of 10 nm to 400 nm.

(10) The semiconductor laser element of (8) or (9), wherein the diffraction grating is located on only one of (i) the one or more linear portions or (ii) the one or more curved portions.

(11) The semiconductor laser element of any one of (1) to (8), wherein:
the first ring resonator includes exactly four linear portions and exactly four curved portions, and
the diffraction grating is located on all of the four linear portions.

(12) The semiconductor laser element of any one of (1) to (8), wherein:
the first ring resonator includes exactly four linear portions and exactly four curved portions, and
the diffraction grating is located on all of the four curved portions.

(13) The semiconductor laser element of any one of (1) to (8), wherein the diffraction grating is located on an entire inner lateral surface of the first ring resonator or on an entire outer lateral surface of the first ring resonator.

(14) The semiconductor laser element according to any one of (1) to (7), wherein the first ring resonator is circular and has a radius in a range of 3 μm to 5000 μm.

(15) The semiconductor laser element of any one of (1) to (14), wherein each of the first semiconductor stack and the second semiconductor stack is made of a group III-V semiconductor material or a group II-VI semiconductor material.

(16) The semiconductor laser element of any one of (1) to (15), wherein the first ring resonator and the second ring resonator comprise a semiconductor stack made of a nitride semiconductor material.

(17) The semiconductor laser element of any one of (1) to (16), further comprising an output waveguide, wherein the output waveguide and the second ring resonator are optically coupled.

(18) The semiconductor laser element of (17), wherein an upper surface of a third active layer of the output waveguide is coplanar with an upper surface of the second active layer.

(19) The semiconductor laser element of (18), wherein the third active layer and the second active layer are formed of the same material.

(20) A method of forming a semiconductor laser element, the method comprising:
forming a semiconductor stack comprising:
   a n-side semiconductor layer,
   a p-side semiconductor layer, and
   an active layer located between the n-side semiconductor layer and the p-side semiconductor layer;
forming a mask on the semiconductor stack, wherein the mask includes a first ring-shaped portion and a second ring-shaped portion, wherein a periodic structure is located at an inner lateral surface or outer lateral surface of the first ring-shaped portion; and
dry etching the semiconductor stack to form a first ring resonator corresponding to the first ring-shaped portion and a second ring resonator corresponding to the second ring-shaped portion, the first ring resonator comprising a diffraction grating corresponding to the periodic structure,
wherein the dry etching is performed at a pressure in a range of 0.1 Pa to 5 Pa.

(21) The method of (20), wherein the dry etching is reactive ion etching utilizing CHF₃/O₂ gas and Cl₂/SiCl₄ gas.

(22) A master oscillator power amplifier comprising:
a first ring resonator comprising:
   a first semiconductor stack comprising a first n-side semiconductor layer, a first p-side semiconductor layer, and a first active layer located between the first n-side semiconductor layer and the first p-side semiconductor layer,
   wherein the first ring resonator comprises a diffraction grating; and
a second ring resonator optically coupled to the first ring resonator by evanescent field coupling, the second ring resonator comprising:
   a second semiconductor stack comprising a second n-side semiconductor layer, a second p-side semiconductor layer, and a second active layer located between the second n-side semiconductor layer and the second p-side semiconductor layer.

While this specification contains many specific implementation details, these should not be construed as limitations on the scope of what may be claimed but rather as descriptions of features specific to particular implementations. Certain features described in this specification in context of separate implementations can also be implemented in combination in a single implementation. Conversely, various features described in the context of a single implementation can also be implemented in multiple implementations separately or in any suitable subcombination. Moreover, although features may be described as acting in certain combination and even initially claimed as such, one or more features from a claimed combination can, in some cases, be excised from the combination, and the claimed combination may be directed to a subcombination or variation of a subcombination.

As utilized herein with respect to numerical ranges, the terms “approximately,” “about,” “substantially,” and similar terms generally mean +/−10% of the disclosed values. When the terms “approximately,” “about,” “substantially,” and similar terms are applied to a structural feature (e.g., to describe its shape, size, orientation, direction, etc.), these terms are meant to cover minor variations in structure that may result from, for example, the manufacturing or assembly step and are intended to have a broad meaning in harmony with the common and accepted usage by those of ordinary skill in the art to which the subject matter of this disclosure pertains. Accordingly, these terms should be interpreted as indicating that insubstantial or inconsequential modifications or alterations of the subject matter described and claimed are considered to be within the scope of the disclosure as recited in the appended claims.

It should be noted that the term “exemplary” and variations thereof, as used herein to describe various embodiments, are intended to indicate that such embodiments are possible examples, representations, or illustrations of possible embodiments (and such terms are not intended to connote that such embodiments are necessarily extraordinary or superlative examples).

Directional terms used herein (e.g., “top,” “bottom,” “above,” “below”) are merely used to describe relative positions, rather than absolute positions. The absolute position of an element may be different in an actual device.

Also, the term “or” is used in its inclusive sense (and not in its exclusive sense) so that when used, for example, to connect a list of elements, the term “or” means one, some or all of the elements in the list. Conjunctive language such as the phrase “at least one of X, Y, or Z,” unless specifically stated otherwise, is otherwise understood with the context as used in general to convey that an item, term, etc. may be either X, Y, Z, X and Y, X and Z, Y and Z, or X, Y, and Z (i.e., any combination of X, Y, and Z). Thus, such conjunctive language is not generally intended to imply that certain embodiments require at least one of X, at least one of Y, and at least one of Z to each be present, unless otherwise indicated.

It is important to note that the construction and arrangement of the devices shown in the various example implementations are illustrative only and not restrictive in character. All changes and modifications that come within the spirit and/or scope of the described implementations are desired to be protected. It should be understood that some features may not be necessary, and implementations lacking the various features may be contemplated as within the scope of the application, the scope being defined by the claims that follow. When the language a “portion” is used, the item can include a portion and/or the entire item unless specifically stated to the contrary.

Although only a few embodiments have been described in detail in this disclosure, those skilled in the art who review this disclosure will readily appreciate that many modifications are possible (e.g., variations in sized, dimensions, structures, shapes, and proportions of the various elements, values of parameters, mounting arrangement, use of materials, colors, orientations, etc.) without materially departing from the novel teachings and advantages of the subject matter described herein. For example, the position of elements may be reversed or otherwise varied and the nature of number of discrete elements or positions may be altered or varied. The order of sequence of any method steps may be varied or re-sequenced according to alternative embodiments. Other substitutions, modifications, changes, and omissions may also be made in the design, operating conditions and arrangement of the various exemplary embodiments without departing from the scope of the present disclosure.

What is claimed is:

1. A semiconductor laser element comprising:
a first ring resonator comprising:
a first semiconductor stack comprising a first n-side semiconductor layer, a first p-side semiconductor layer, and a first active layer located between the first n-side semiconductor layer and the first p-side semiconductor layer,
wherein the first ring resonator comprises a diffraction grating; and
a second ring resonator optically coupled to the first ring resonator by evanescent field coupling, the second ring resonator comprising:
a second semiconductor stack comprising a second n-side semiconductor layer, a second p-side semiconductor layer, and a second active layer located between the second n-side semiconductor layer and the second p-side semiconductor layer;
wherein a peak wavelength of light emitted by the second ring resonator is the same as a peak wavelength of light emitted by the first ring resonator.

2. The semiconductor laser element of claim 1, wherein the first active layer and the second active layer are formed of the same material.

3. The semiconductor laser element of claim 1, wherein an upper surface of the first active layer and an upper surface of the second active layer are coplanar.

4. The semiconductor laser element of claim 1, wherein the diffraction grating is disposed on at least one of an inner lateral surface of the first ring resonator and an outer lateral surface of the first ring resonator.

5. The semiconductor laser element of claim 1, wherein the diffraction grating is disposed on an upper surface of the first ring resonator.

6. The semiconductor laser element of claim 1, wherein the diffraction grating is embedded in the first ring resonator.

7. The semiconductor laser element of claim 1, wherein:
the first ring resonator includes one or more linear portions and one or more curved portions, and
a distance between the first ring resonator and the second ring resonator is at a minimum at one of the one or more linear portions.

8. The semiconductor laser element of claim 7, wherein the distance is in a range of 10 nm to 400 nm.

9. The semiconductor laser element of claim 7, wherein the diffraction grating is located on only one of (i) the one or more linear portions or (ii) the one or more curved portions.

10. The semiconductor laser element of claim 1, wherein:
the first ring resonator includes exactly four linear portions and exactly four curved portions, and
the diffraction grating is located on all of the four linear portions.

11. The semiconductor laser element of claim 1, wherein:
the first ring resonator includes exactly four linear portions and exactly four curved portions, and
the diffraction grating is located on all of the four curved portions.

12. The semiconductor laser element of claim 1, wherein the diffraction grating is located on an entire inner lateral surface of the first ring resonator or on an entire outer lateral surface of the first ring resonator.

13. The semiconductor laser element of claim 1, wherein the first ring resonator is circular and has a radius in a range of 3 μm to 5000 μm.

14. The semiconductor laser element of claim 1, wherein each of the first semiconductor stack and the second semiconductor stack is made of a group III-V semiconductor material or a group II-VI semiconductor material.

15. The semiconductor laser element of claim 11, wherein the first ring resonator and the second ring resonator comprise a semiconductor stack made of a nitride semiconductor material.

16. The semiconductor laser element of claim 1, further comprising an output waveguide, wherein the output waveguide and the second ring resonator are optically coupled.

17. The semiconductor laser element of claim 16, wherein an upper surface of a third active layer of the output waveguide is coplanar with an upper surface of the second active layer.

18. The semiconductor laser element of claim 17, wherein the third active layer and the second active layer are formed of the same material.

19. A method of forming a semiconductor laser element, the method comprising:
forming a semiconductor stack comprising:
a n-side semiconductor layer,
a p-side semiconductor layer, and
an active layer located between the n-side semiconductor layer and the A-side semiconductor layer;
forming a mask on the semiconductor stack, wherein the mask includes a first ring-shaped portion and a second ring-shaped portion, wherein a periodic structure is located at an inner lateral surface or outer lateral surface of the first ring-shaped portion; and
dry etching the semiconductor stack to form a first ring resonator corresponding to the first ring-shaped portion and a second ring resonator corresponding to the second ring-shaped portion, the first ring resonator comprising a diffraction grating corresponding to the periodic structure,
wherein the dry etching is performed at a pressure in a range of 0.1 Pa to 5 Pa.

20. The method of claim 19, wherein the dry etching is reactive ion etching utilizing CHF₃/O₂ gas and Cl₂/SiCl₄ gas.
